(19) United States
(12) Patent Application Publication
(10) Pub. No.: US 2005/0191564 A1
(43) Pub. Date: Sep. 1, 2005

(54) Liner mask for semiconductor applications

(76) Inventors: Teng-Wang Huang, Dresden (DE); Kristin Schupke, Dresden (DE); Hai-Han Hung, Dresden (DE)

Correspondence Address: BRINKS HOFER GILSON & LIONE;INFINEON, PO BOX 10395, CHICAGO, IL, 60610, US

(21) Appl. No.: 10/789,118

(22) Filed: Feb. 27, 2004

(51) Int. Cl. G03F 9/00

(52) U.S. Cl. 430/5

(57) ABSTRACT

A method for producing a liner mask on a semiconductor structure is disclosed. The method may include providing an amorphous liner layer (55) on the top side (OS;OS′) of the semiconductor structure, annealing the amorphous liner layer (55) to increase the crystallisation and generate a semi-crystalline liner layer (55); implanting (I1) extrinsic ions in a subregion (55a) of the semi-crystalline liner layer (55) to decrease the etching rate of the subregion (55a) and create an etch selectivity between the to the subregion (55a) complementary subregion (55b) and the subregion (55a) in the predetermined etchant; and selectively removing of the to the subregion (55a) complementary subregion (55b) opposite to the subregion (55a) in a etching step in the predetermined etchant for completing the liner mask.

### BACKGROUND OF THE INVENTION

1. Technical Field

The present invention generally relates to semiconductor applications. In particular, the present invention relates to methods, processes, systems for producing a liner mask on a semiconductor structure and corresponding applications.

2. Related Art

Although applicable in principle to any integrated circuit, the present invention and the problem area on which it is based are explained with regard to integrated memory circuits in silicon technology.

In a prior art patent application DE 102 55 845.0, the production of a liner mask in a trench by means of an implantation of boron ions in definite regions in an amorphous silicon liner and following selective wet etching in NH₄OH is disclosed.

For the known method, the fact that the selectivity between an amorphous non-implanted silicon and the amorphous implanted silicon having only a factor 8-10 has been found to be a disadvantage. This leads to increasing aspect ratios and decreasing liner layers dispersion phenomena appearing at the implantation cause an implantation of unwished regions and thereby a mask erosion on this unwished regions at the following etching.

In particular, the sequential execution of several implantation steps, for example with the same inclination opposite the vertical axis and different rotations angles around the vertical axis, the dispersion probability is increased and thereby the above-mentioned problems are increased.

Accordingly, there is a need for a method for producing a liner mask on a semiconductor structure that is less vulnerable to above-mentioned dispersion problems.

### BRIEF SUMMARY

The above problems have been solved with the present invention. By way of introduction only, an object of the present invention is to specify a method for producing a liner mask on a semiconductor structure that is less vulnerable to above-mentioned dispersion problems.

According to the invention, this object may be achieved by a method for producing a liner mask on a semiconductor structure including providing an amorphous liner layer on a top side of the semiconductor structure in a deposition process at a first temperature; annealing the amorphous liner layer at a second temperature, which is higher than the first temperature; performing an implantation of extrinsic ions in a subregion of the at least semi-crystalline liner layer for decreasing the etching rate of the subregion in the predetermined etchant and creating a etch selectivity between the subregion complementary subregion and the subregion in the predetermined etchant; and selectively removing of the to the subregion complementary subregion opposite to the subregion in a etching step in the predetermined etchant for completing the liner mask.

An object of the present invention may be achieved by means of an application of a use of a liner mask for a trench capacitor with an isolation collar in a substrate that is single-sided electrically connected with the substrate by means of a buried contact, in particular for a semiconductor memory cell with a planar selection transistor provided in the substrate and connected over the buried contact, whereas the liner mask is produced for defining a single-sided contact region and an other-sided isolation region of the buried contact in a trench for the trench capacitor.

An advantage of the method and its application according to the invention is an increase in the selectivity for producing a liner mask to be many times higher than the prior art.

The present invention may include an annealing step for increasing the crystallization degree of the liner layer before an implantation step. Due to increase in selectivity, removing the non-implanted liner region by means of the etching step that follows the implantation step becomes easier. Thus, the dispersion phenomena do not have such a high impact, and the mask erosion may be prevented.

In accordance with an embodiment, the liner layer consists of silicon, whereas the extrinsic ions are boric ions or boron ions.

In accordance with an embodiment, the semiconductor structure comprises a trench, whereas the implantation is made in such a manner that the complementary subregion lies in the trench.

In accordance with an embodiment, the first temperature is between approximately 400° C. and 600° C., and the second temperature lies between approximately 700° C. and 100° C.

In accordance with an embodiment, a further liner layer is provided on the top side of the semiconductor structure underneath a liner layer, whereas on the further liner layer the etching step for the selective removal of the complementary subregion stops.

The foregoing discussion of the summary is provided only by way of introduction. Other systems, methods, processes, apparatuses, features and advantages of the invention will be, or will become, apparent to one with skill in the art upon examination of the following figures and detailed description. It is intended that all such additional systems, methods, features and advantages be included within this description, be within the scope of the invention, and may be realized and obtained by means of the instrumentalities and combinations particularly pointed out in the claims.

### BRIEF DESCRIPTION OF THE DRAWINGS

The invention can be better understood with reference to the following drawings and description. The components in the figures are not necessarily to scale, emphasis instead being placed upon illustrating the principles of the invention. Moreover, in the figures, like referenced numerals designate corresponding parts throughout the different views.

FIGS. 1A and 1B show schematic views of method steps for producing a liner mask on a semiconductor structure as an embodiment according to the present invention;

FIGS. 2A-2G show schematic views of method steps for producing a liner mask on a semiconductor structure as a second embodiment according to the present invention.

### DETAILED DESCRIPTION OF THE PREFERRED EMBODIMENT

Exemplary embodiments of the invention are illustrated in the drawings and explained in more detail in the description below.

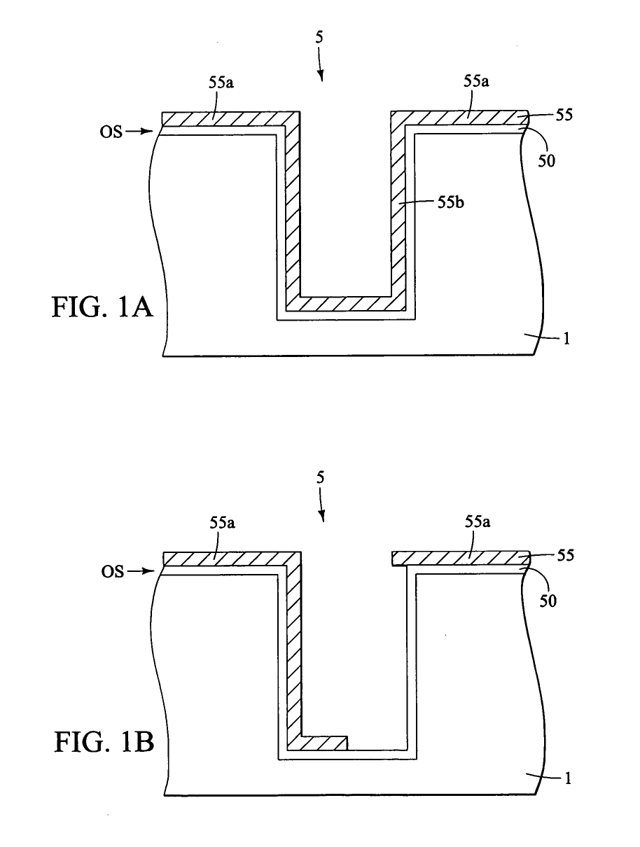

FIGS. 1A and 1B are schematic views of successive method steps of a method for producing a liner mask on a semiconductor structure as a first embodiment according to the invention.

In FIG. 1A, reference symbol 5 designates a trench provided in the silicon semiconductor substrate 1. On the top side OS of the semiconductor substrate 1, a silicon nitride liner layer 50 and an underneath lying silicon liner layer 55 of amorphous undoped silicon are provided, (e.g. with a CVD-step at 500° C.)

Then, in a separate fast annealing step, the silicon liner 55 may be tempered at 900° C. for 30 seconds in N₂ to increase its crystallization degree and thereby its etching rate in NH₄OH.

Afterwards, with reference to FIG. 1B, it follows an inclined implantation I1 with a predetermined angle opposite of the vertical axis, (e.g. 30°), whereas BF₂ is implanted at an energy 10 keV with a dose of 3×10⁴ cm² in the subregion 55a of the silicon liner 55 and the region 55b remains shadowed against the implantation. Thus, the etching characteristics of the boron-contaminated region 55a of the silicon liner 55 changes, which is utilized according to FIG. 1B, with selectively removing of the region 55b by means of an adequate wet etching step in NH₄OH for uncovering the underneath lying silicon nitride liner layer 50 on which the wet etching step in NH₄OH stops.

The selectivity between the (partially) crystalline implanted silicon layer region 55a and the (partially) crystalline non-implanted silicon liner region 55b at the wet etching step amounts to 63.4 at the mentioned example.

Thus, a liner mask is produced from the liner 55, by means of which further selective etching steps in the underneath lying semiconductor structure can be done.

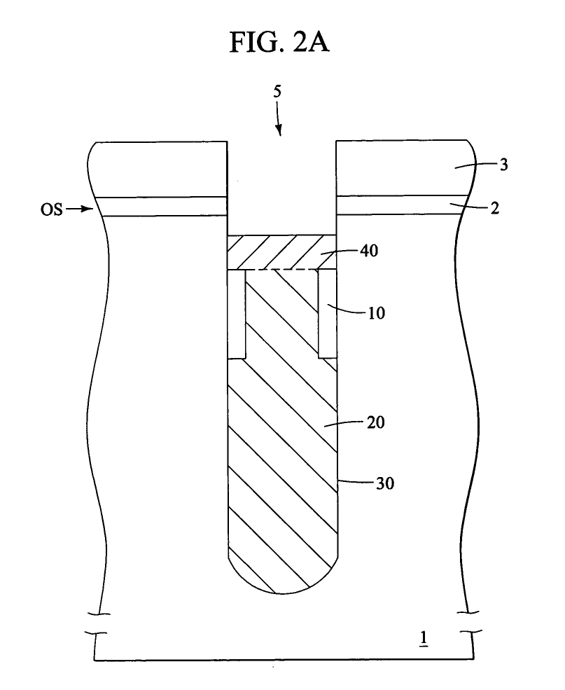

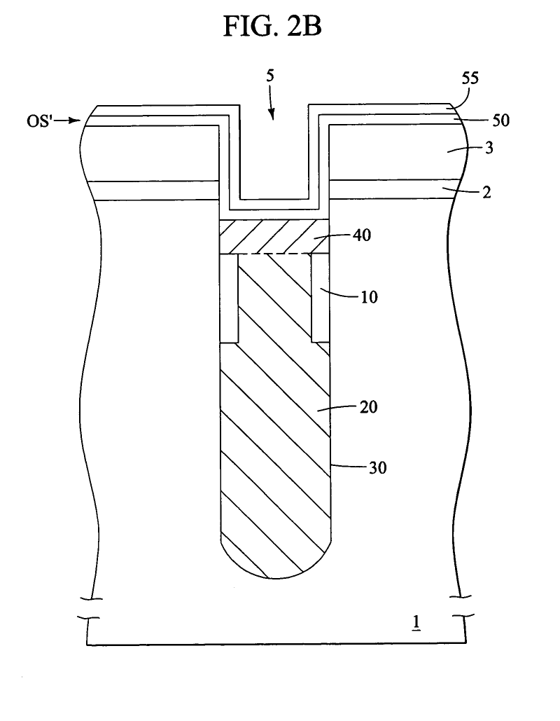

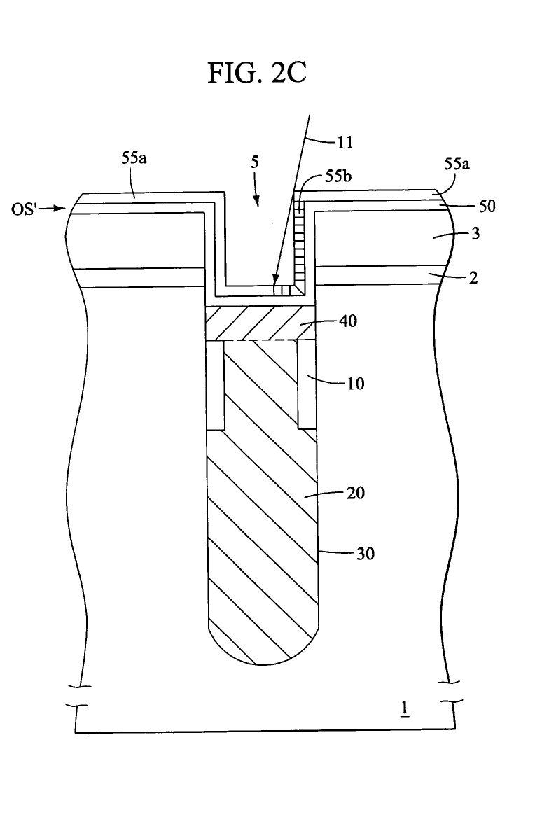

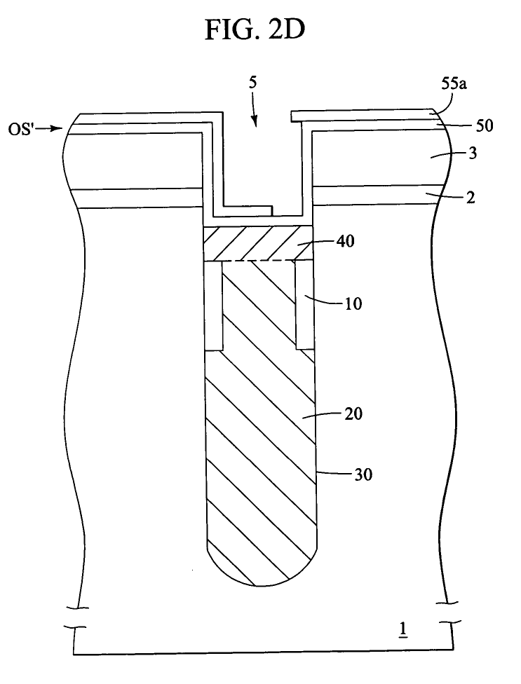

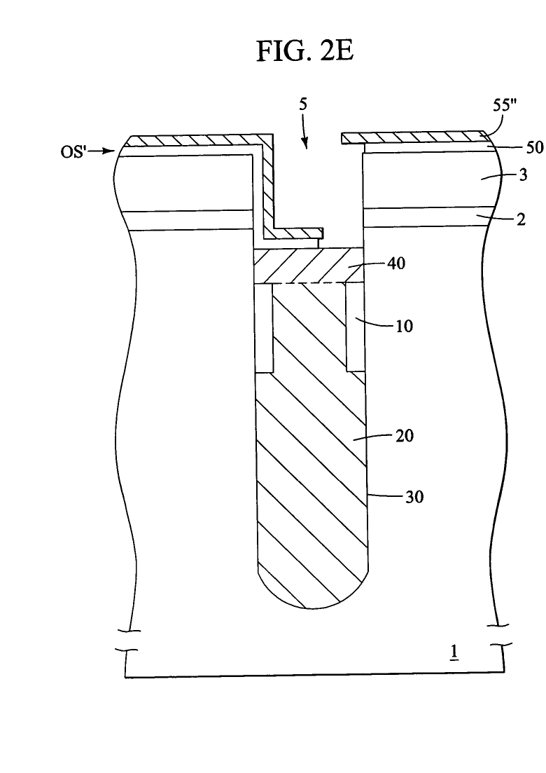

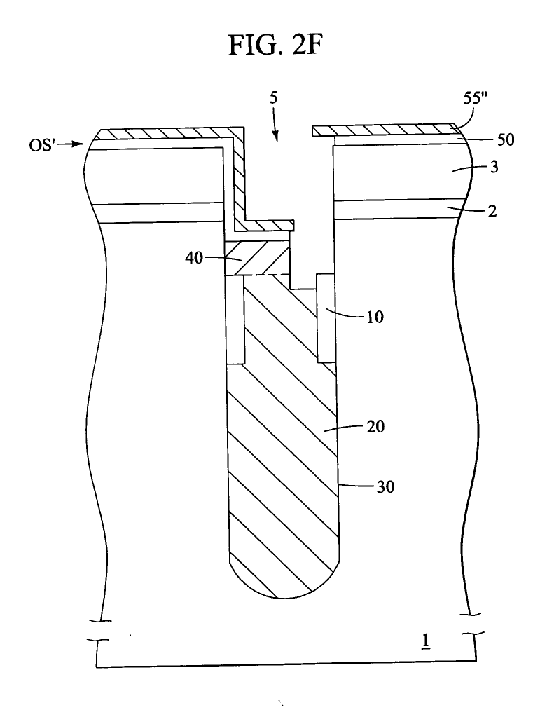

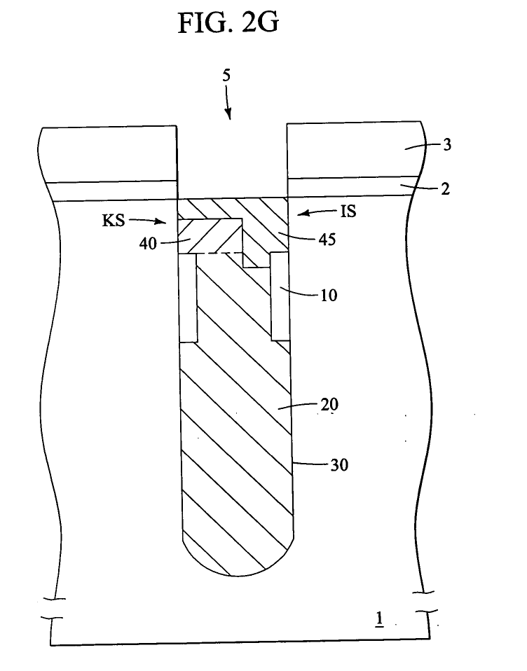

FIGS. 2A-2G are schematic views of successive method steps of a method for producing a liner mask on a semiconductor structure as a second embodiment according to the invention.

In FIG. 2A, reference symbol 5 designates a trench provided in the silicon semiconductor substrate 1. On the top side OS of the semiconductor substrate 1, a hardmask is provided consisting of a pad oxide layer 2 and a pad nitride layer 3. In the lower and middle region of the trench 5, a dielectric 30 is provided which isolates an electrically conductive filling 20 opposite to the surrounding semiconductor substrate 1.

In the upper and middle region of trench 5, a revolving isolation collar 10 is provided that is exactly deepened in the trench 5 like the conductive filling 20. For example, a material for the isolation collar 10 is silicon oxide, and a material for the electrically conductive filling 20 is polysilicon. But, of course, other materials may be used.

In addition, a conductive filling 40 embedded under the top side OS and consisting of epi-polysilicon is provided. Thus, the conductive filling 40 describes a circumferentially connected buried contact that has to be partially removed for forming an isolation region IS later. As to realize the single-sided connection of the region 40 to the semiconductor substrate 1, the below-mentioned “subtractive” method steps are performed.

In accordance with FIG. 2B, on the top side OS′ of the semiconductor structure, a silicon nitride liner layer 50 and a above-lying silicon liner layer 55 of amorphous undoped silicon are provided, (e.g., in a CVD step at 500° C.).

Then, in a separate fast annealing step, the silicon liner 55 is tempered at 900° C. for 30 s in N₂ for increasing the crystallization degree and thereby the etching rate in NH₄OH.

In accordance with FIG. 2C, it follows in the following an inclined implantation I1 with a predetermined angle opposite to the vertical axis, (e.g. 30°), whereas BF₂ at an energy 5 keV with a dose of 3×10¹⁴ cm⁻² is implanted in the region 55a of the silicon liner 55, and a region 55b remains shadowed against the implantation. Thus, the etching characteristics of the boron-contaminated region 55a of the silicon liner 55 changes which is utilized, in accordance with FIG. 2D, for selectively removing the region 55b by means of an adequate wet etching step in NH₄OH in order to uncover the silicon nitride liner layer 50 lying underneath on which the wet etching step in NH₄OH stops.

The selectivity between the (partially) crystalline implanted silicon liner region 55a and the (partially) crystalline non-implanted silicon liner region 55b at the wet etching step amounts to 63.4 at the example mentioned above.

Thus, a liner mask is produced from the liner 55, by means of which further selective etching steps in the underneath-lying semiconductor substrate in accordance with FIGS. 2E-2G can be performed.

In accordance with FIG. 2E, it follows a wet oxidation of the remaining implanted region 55a of the liner 55 getting a adequate oxidized liner region 55″. In the following process step, a part of the silicon nitride liner 50 is removed from the surface of the conductive region 40 and from the side wall of the trench 5 or of the hardmask 2, 3 by use of the oxidized implanted region 55″ of the liner 55.

In accordance with FIG. 2F, it follows in the following an etching of the conductive filling 40 and of a part of the conductive filling 20 by use of the region 55″ as a mask.

Thus, in the process state as shown in FIG. 2F, a part of the region 40 being used as a buried contact is removed, and then, at the adequate place, an adequate to the top and to the side isolating oxide filling 45 can be provided by means of depositing and back-etching in the further proceeding of the method, after the liners 50, 55 (55″) have been removed from the surface, as is shown in FIG. 2G. This forms a buried contact with the connection region KS and the isolation region IS.

Although the present invention has been described above on the basis of a preferred exemplary embodiment, it is not restricted thereto, but rather can be modified in diverse ways.

In particular, the selection of the layer materials is only by way of example and can be varied in many different ways.

Although the annealing step in the above-mentioned example was conducted at approximately 900° C., one or more temperatures are possible in the range of 700° C.-1100° C. Also, the deposition temperature of the liner layers can lie in the range of approximately 400° C.-600° C., although it amounts to 500° C. in the above-mentioned example.

While the above embodiments have been described, those skilled in the art will recognize that the advantages may be extended to various semiconductors and various processes. Accordingly, the invention is not to be restricted except in light as necessitated by the accompanying claims and their equivalents.

### LIST OF REFERENCE SYMBOLS

1 Si-semiconductor substrate
OS, OS′ top side
2 pad oxide
3 pad nitride
5 trench
40 conductive epitaxial region
10 isolation collar
20 conductive filling (e.g. polysilicon)
30 capacitor dielectric
KS contact region
IS isolation region
50 silicon nitride liner
55 liner of amorphous undoped silicon
55a implanted region of 55
55b shadowed region of 55
55″ oxidized implanted region of 55b
I1 implantation

1. A method for producing a liner mask on a semiconductor structure comprising:
providing an amorphous liner layer on a top side of the semiconductor structure in a deposition process at a first temperature;
annealing the amorphous liner layer at a second temperature, being higher than the first temperature, for increasing a degree of crystallisation and for generating at least a semi-crystalline liner layer whose etching rate in a predetermined etchant is higher than an etching rate of the amorphous liner layer;
performing an implantation of extrinsic ions in a subregion of the at least semi-crystalline liner layer for decreasing the etching rate of the subregion in the predetermined etchant and creating a etch selectivity between the subregion complementary subregion and the subregion in the predetermined etchant; and
selectively removing of the to the subregion complementary subregion opposite to the subregion in a etching step in the predetermined etchant for completing the liner mask.

2. The method of claim 1, where the semiconductor structure comprises a trench and that the implantation is performed so that the complementary subregion lies in the trench.

3. The method of claim 2, where the first temperature is between approximately 400° C. and approximately 600° C. and the second temperature is between approximately 700° C. and 1100° C.

4. The method of claim 1, where on the top side of the semiconductor structure underneath the liner layer, a further liner layer is provided, on which the etching step for selectively removing of the complementary subregion stops.

5. The method of claim 4, where the first temperature is between approximately 400° C. and approximately 600° C. and the second temperature is between approximately 700° C. and 1100° C.

6. The method of claim 1, where the first temperature is between approximately 400° C. and approximately 600° C. and the second temperature is between approximately 700° C. and 1100° C.

7. The method of claim 6, where the semiconductor structure comprises a trench and that the implantation is performed so that the complementary subregion lies in the trench.

8. The method of claim 1, wherein the liner layer includes silicon and the extrinsic ions include boric ions or boron ions.

9. The method of claim 8, where the semiconductor structure comprises a trench and that the implantation is performed so that the complementary subregion lies in the trench.

10. The method of claim 9, where on the top side of the semiconductor structure underneath the liner layer, a further liner layer is provided, on which the etching step for selectively removing of the complementary subregion stops.

11. The method of claim 10, where the first temperature is between approximately 400° C. and approximately 600° C. and the second temperature is between approximately 700° C. and 1100° C.

12. A liner mask for a trench capacitor comprising an isolation collar in a substrate being single-sided electrically connected with the substrate by a buried contact, for a semiconductor memory cell with a planar selection transistor provided in the substrate and connected over the buried contact, where the liner mask defines a single-sided contact region and an other-sided isolation region of the buried contact in a trench for the trench capacitor.

13. The liner mask of claim 12, where the trench for the trench capacitor comprises a conductive filling with a region filling the trench above the isolation collar and from which a subregion is removed using the liner mask and which is filled with an isolating filling in the following for completing the isolating region.

14. The liner mask of claim 13 where the subregion is transformed into an oxidized subregion after the selective etching by means of an oxidation.
